(19) United States
(12) Patent Application Publication
(10) Pub. No.: US 2010/0224870 A1
(43) Pub. Date: Sep. 9, 2010

(54) FIELD EFFECT TRANSISTOR

(75) Inventors: Tatsuya Iwasaki, Machida-shi (JP); Naho Itagaki, Yokohama-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/681,793

(22) PCT Filed: Dec. 2, 2008
(86) PCT No.: PCT/JP2008/072222

§ 371 Date: Apr. 6, 2010

(30) Foreign Application Priority Data
Dec. 13, 2007 (JP) 2007-322148

(51) Int. Cl. H01L 33/16; H01L 29/786

(52) U.S. Cl. 257/43; 257/59; 257/57; 257/E29.296; 257/E33.053

(57) ABSTRACT

A field effect transistor includes at least a channel layer, a gate insulation layer, a source electrode, a drain electrode, and a gate electrode. The channel layer is formed from an amorphous oxide material that contains at least In and Mg, and an element ratio, expressed by Mg/(In+Mg), of the amorphous oxide material is 0.1 or higher and 0.48 or lower.

### TECHNICAL FIELD

The present invention relates to a field effect transistor using an amorphous oxide. More particularly, the present invention relates to a field effect transistor using an amorphous oxide as a channel layer.

### BACKGROUND ART

Field effect transistors (FETs) are electronic active devices with a gate electrode, a source electrode, and a drain electrode that control electric current between the source electrode and the drain electrode by controlling the flow of electric current into a channel layer through voltage application to the gate electrode. FETs that use as the channel layer a thin film formed on an insulated substrate such as a ceramic, glass, or plastic substrate, in particular, are called thin film transistors (TFTs).

The above-mentioned TFTs are formed by using a thin film technology, and hence the TFTs have an advantage of being easily formed on the substrate having a relatively large area, and therefore are widely used as a driving device for a flat panel display device such as a liquid crystal display device. In an active matrix liquid crystal display device (ALCD) each image pixel is turned on/off by using TFTs formed on a glass substrate. Further, in a future high performance organic LED display (OLED), current drive for each pixel by TFTs is thought to be effective. In addition, a liquid crystal display device having a higher performance is realized in which a TFT circuit having a function of driving and controlling an entire image is formed on a substrate placed in the peripheral of an image display region.

The most popular TFTs are ones that use a polycrystalline silicon film or an amorphous silicon film as the channel layer. For pixel driving, amorphous silicon TFTs have been put into practical use. For overall image driving/controlling, polycrystalline silicon TFTs have been put into practical use.

However, it is difficult to produce an amorphous silicon TFT, a polysilicon TFT, and other TFT's on a substrate such as a plastic plate or foil since high-temperature processing is demanded for device production.

Meanwhile, the development of flexible displays in which a TFT formed on a polymer plate or a foil serves as a drive circuit of an LCD or of an OLED has become active in recent years. This is drawing attention to organic semiconductor films, which can be formed at low temperature on a plastic film or the like.

Pentacene is an example of organic semiconductor films of which research and development is being advanced. It has been reported that the carrier mobility of pentacene is about 0.5 cm²/Vs, which is equivalent to the carrier mobility in amorphous Si-MOSFETs.

However, pentacene and other organic semiconductors have problems of being low in thermal stability (<150° C.) and being toxic (carcinogenic), and therefore have not succeeded in producing a device fit for practical use.

Another material that is drawing attention as being applicable to the channel layer of a TFT is oxide material.

For example, TFTs using as the channel layer of ZnO are being developed actively. The ZnO film can be formed on a plastic plate, a foil, or other similar substrates at relatively low temperature. However, ZnO cannot form a stable amorphous phase at room temperature and forms a polycrystalline phase instead, which causes electron scattering in the polycrystalline grain boundaries and makes it difficult to increase the electron mobility. In addition, the size of polycrystalline grains are greatly varied and their interconnections are significantly influenced by the film formation method. Therefore, TFT characteristics may scatter from device to device and lot to lot.

A TFT that uses an In—Ga—Zn—O-based amorphous oxide has been reported (K. Nomura et. al, Nature vol. 432, pp. 488-492 (2004-11)). This transistor can be formed on a plastic or glass substrate at room temperature. The transistor also accomplishes the normally-off type transistor characteristics at a field effect mobility of about 6 to 9. Another advantageous characteristic is that the transistor is transparent with respect to visible light. The above-mentioned document describes a technique of using an amorphous oxide that has a composition ratio of In:Ga:Zn=1.1:1.1:0.9 for the channel layer of a TFT.

While an amorphous oxide using three metal elements, In, Ga, and Zn is employed in K. Nomura et. al, Nature vol. 432, pp. 488-492 (2004-11) as described above, it is better in terms of ease of composition control and material adjustment if fewer metal elements are used. On the other hand, oxides that use one type of metal element, such as ZnO and In₂O₃, generally form polycrystalline thin films when deposited by sputtering or a similar method, and accordingly cause the above-mentioned fluctuations (device to device variation and lot to lot variation) in characteristics of a TFT device.

Applied Physics Letters 89, 062103 (2006) describes an In—Zn—O-based amorphous oxide as an example of using two types of metal element. This oxide, containing two types of metal element, is free from the above-mentioned problem. Further, it has been known that a TFT that employs an In—Zn—O-based amorphous oxide has optical sensitivity in the near-UV region of the visible range (wavelength: 380 nm, 450 nm, 550 nm) (Journal of Non-Crystalline Solids Volume 352, Issues 9-20, 15 Jun. 2006, pages 1756-1760).

To use the TFT containing an In—Zn—O-based amorphous oxide which is described in Journal of Non-Crystalline Solids Volume 352, Issues 9-20, 15 Jun. 2006, pages 1756-1760 stably in a bright place, it is desirable to make the optical sensitivity of the TFT be lower. This is because a display employing a TFT is sometimes operated under visible light. For instance, a TFT could be irradiated with light that is used to display an image, or light that enters from the outside. When the channel layer of a TFT has a certain level of optical sensitivity, the electric characteristics of the channel layer are varied depending on the amount of light irradiation, with the result that the operation of the TFT is made unstable. One way to avoid this adverse effect of light is providing the display with a light-shielding layer, but completely eliminating stray light puts severe limitation on the structure of the display. It is therefore desired to employ a TFT containing an amorphous oxide that contains as few elements as possible and having low visible light sensitivity.

Improving the environmental stability is also desired because, according to a study conducted by the inventors of the present invention, the resistivity of an In—Zn—O-based amorphous oxide could be varied with time when the oxide is stored in atmospheric air.

### DISCLOSURE OF THE INVENTION

The present invention has been made in view of the above-mentioned problem, it is therefore an object of the present invention to provide a thin film transistor that uses an amorphous oxide containing a few elements, that has an excellent environmental stability such as one inflicted during storage in atmospheric air, and that has a low sensitivity with respect to visible light.

A field effect transistor according to the present invention includes at least a channel layer, a gate insulation layer, a source electrode, a drain electrode, and a gate electrode, which are formed on a substrate. The channel layer is formed from an amorphous oxide material that contains at least In and Mg, and an element ratio, Mg/(In+Mg), of the amorphous oxide material is 0.1 or higher and 0.48 or lower.

According to the present invention, the field effect transistor having excellent characteristics can be realized by forming the channel layer from the amorphous oxide that contains In and Mg (or Al). Especially a transistor with low visible light sensitivity, in other words, very stable against light irradiation, can be obtained. Thus, when applied to a display, the TFT can operate stably in a bright place as well.

Further, the transistor of the present invention undergoes substantially no changes in characteristics with time during storage in atmospheric air, and therefore has an excellent environmental stability.

Further features of the present invention will become apparent from the following description of exemplary embodiments with reference to the attached drawings.

### BRIEF DESCRIPTION OF THE DRAWINGS

FIG. 1 is a graph comparing off-current values of an In—Mg—O-based thin film transistor, an In—Al—O-based thin film transistor, and an In—Ga—O-based thin film transistor under light irradiation.

FIG. 2 is a graph illustrating changes in TFT transfer characteristics with an irradiation of light.

FIG. 3 is a graph illustrating changes with time in resistivity of an In—Mg—O thin film, an In—Al—O thin film, an In—Zn—O thin film, and an In—Sn—O thin film.

FIG. 4 is a graph illustrating an example of transfer characteristics of the In—Mg—O-based thin film transistors and their composition dependency.

FIG. 5 is a graph illustrating an example of transfer characteristics of the In—Al—O-based thin film transistors and their composition dependency.

FIGS. 6A and 6B are graphs illustrating composition dependency of TFT characteristics (6A: field effect mobility, 6B: threshold voltage Vth) of an In—Mg—O-based thin film transistor.

FIGS. 7A and 7B are graphs illustrating composition dependency of TFT characteristics (7A: field effect mobility, 7B: threshold voltage Vth) of an In—Al—O-based thin film transistor.

FIGS. 8A, 8B and 8C are sectional views illustrating structural examples of the thin film transistor according to the present invention.

FIGS. 9A and 9B are graphs illustrating examples of characteristics of the thin film transistor according to the present invention.

FIG. 10 is a diagram illustrating a configuration of a thin film forming apparatus for manufacturing the thin film transistor according to the present invention.

FIG. 11 is a graph illustrating optical absorption spectra of an In—Mg—O thin film, an In—Al—O thin film, and an In—Zn—O thin film.

### BEST MODE FOR CARRYING OUT THE INVENTION

An embodiment of a field effect transistor according to the present invention will be described below.

The inventors of the present invention have conducted an extensive research on oxide materials containing two types of metal element, such as an oxide containing In and Mg and an oxide containing In and Al, as a material for a channel layer of a field effect transistor.

FIG. 11 illustrates wavelength dependence of optical absorption of thin films formed by sputtering. Each oxide of FIG. 11 contains In and another metal element, M, at an element ratio, M/(In+M), of about 0.3 (30 atom %). The absorption coefficient was measured by with the use of a spectroscopic ellipsometry manufactured by J. A. Woollam Co., Inc., where Tauc-Lorentz optical model was used for a fitting analysis.

As can be seen in FIG. 11, compared to an oxide containing In and Zn (In—Zn—O), the optical absorption of an oxide containing In and Mg (In—Mg—O) and an oxide containing In and Al (In—Al—O) remains small at short wavelengths.

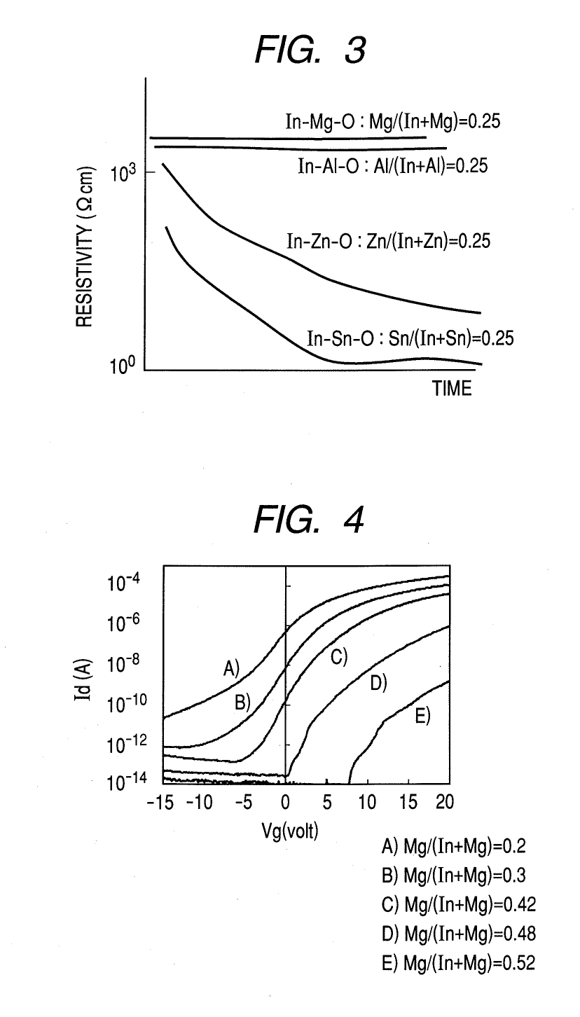

FIG. 3 illustrates resistivity changes with time in air for thin films formed by sputtering. Each oxide of FIG. 3 contains In and another metal element, M, at an element ratio, M/(In+M), of about 0.25. As illustrated in FIG. 3, resistivity of an oxide containing In and Zn (In—Zn—O) and an oxide containing In and Sn (In—Sn—O) change significantly with time. Resistivity of an oxide containing In and Mg (In—Mg—O) and that of an oxide containing In and Al (In—Al—O), on the other hand, hardly change with time. Electrical property of In—Mg—O and In—Al—O are stable in air and thus are preferable for the channel material.

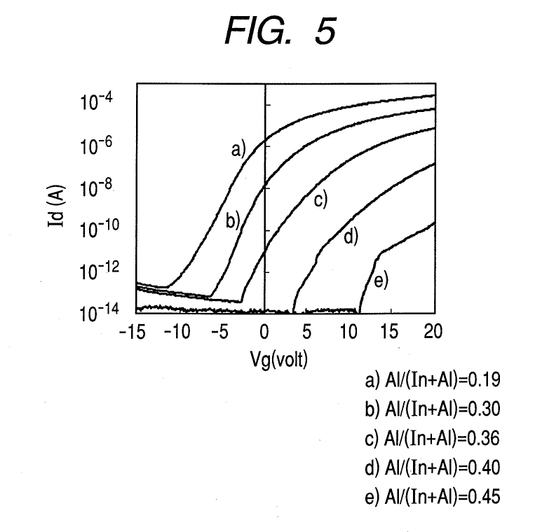

Next, TFTs with channel layers of the above-mentioned materials are separately formed. With In—Zn—O and with In—Sn—O, it was difficult to obtain a transistor having an on/off ratio of five digits or more. TFTs with channels of In—Al—O and In—Mg—O, on the other hand, succeeded in switching with an on/off ratio of six digits or more (see transfer characteristics (Id-Vg graphs) of FIGS. 4 and 5). FIGS. 4 and 5 illustrate characteristics of five different transistors which differ in metal element ratio.

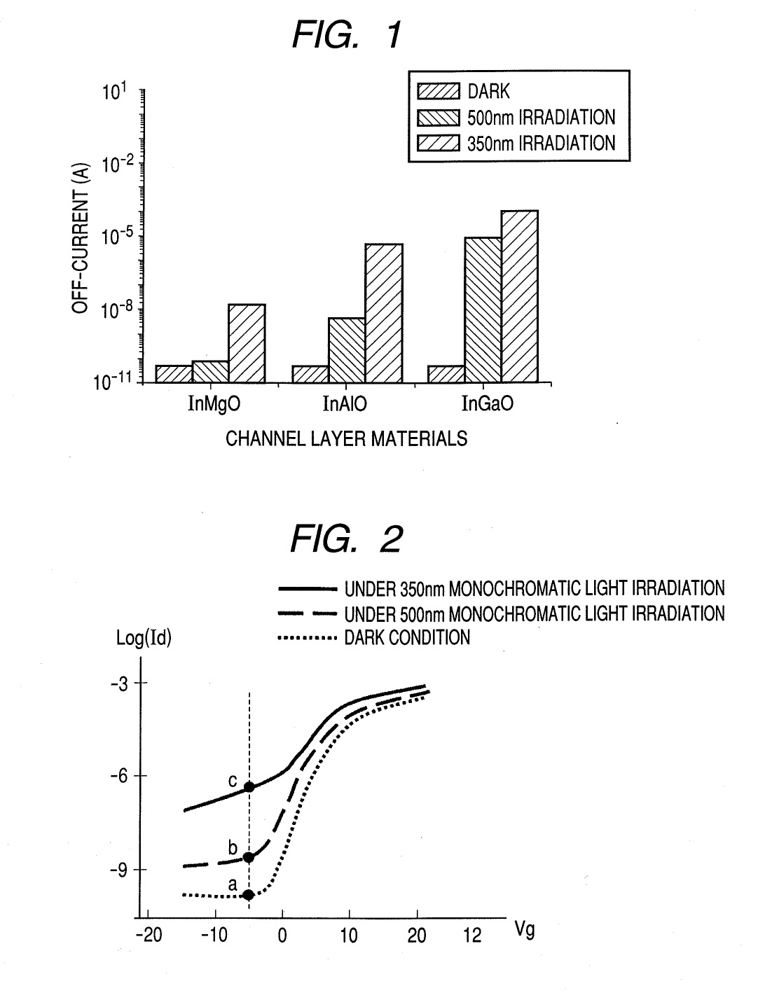

An optical response characteristic of a thin film transistor will be described next. FIG. 2 is a graph illustrating a transistor characteristic (Id-Vg) difference between an amorphous oxide TFT (such as an In—Mg—O TFT, an In—Al—O TFT, or an In—Ga—O TFT) in a dark place and the TFT irradiated with light. As illustrated in FIG. 2, an off-current of the TFT has a very small value (a) in a dark place, whereas the off-current increases to (b) and (c) when the TFT is irradiated with monochromatic light at the wavelength of 500 nm and 350 nm, respectively. In short, the off-current increases under light irradiation, and thereby the on/off ratio is reduced. A graph of FIG. 1 compares the off-current measured in a dark place, that under the irradiation with 500-nm monochromatic light, and that under the irradiation with 350-nm monochromatic light. Here, off-current values of TFTs using In—Mg—O, In—Al—O, and In—Ga—O as their channel layers are compared each other. As can be seen in FIG. 1, the increase in off-current under light irradiation is smaller with In—Mg—O and In—Al—O than with In—Ga—O. With In—Mg—O, in particular, the change in off-current under light irradiation is smallest. This proves that a thin film transistor in which In—Mg—O, In—Al—O, or a similar amorphous oxide material is employed for a channel layer has a superior stability against light irradiation.

The inventors of the present invention thus found out that an oxide containing In and Mg (or Al) is a preferred material for a channel layer.

A detailed description will be given next on a structure of the field effect transistor according to the present invention.

The field effect transistor according to the present invention is an electronic active device including a three-terminal of a gate electrode, a source electrode, and a drain electrode. The field effect transistor has a function of applying voltage Vg to the gate electrode, controlling a current Id flowing through the channel layer, and switching the current Id between the source electrode and the drain electrode.

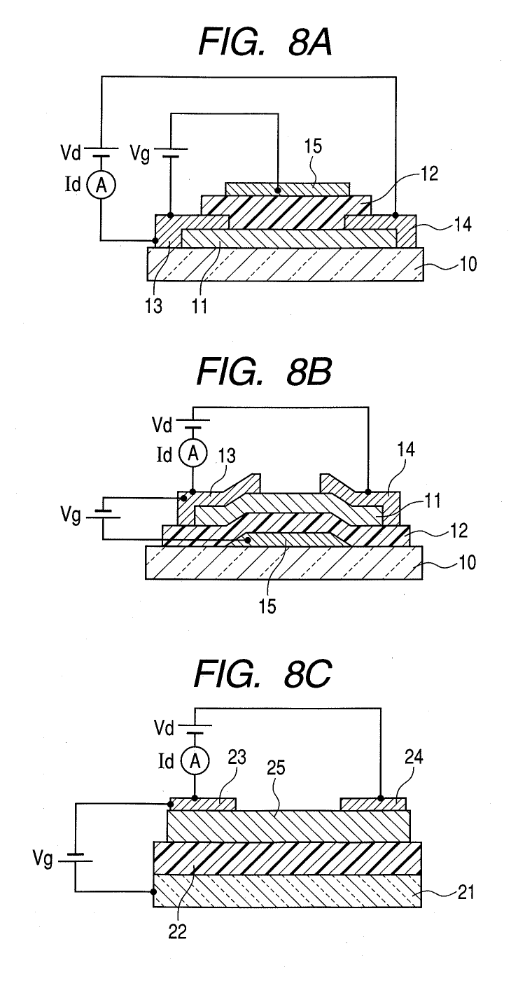

FIGS. 8A, 8B and 8C are sectional views illustrating structural examples of a thin film transistor according to the present invention. FIG. 8A illustrates an example of a top-gate structure in which a gate insulation layer 12 and a gate electrode 15 are sequentially formed on a channel layer 11 provided on a substrate 10. FIG. 8B illustrates an example of a bottom-gate structure in which the gate insulation layer 12 and the channel layer 11 are sequentially formed on the gate electrode 15. In FIGS. 8A and 8B, a source electrode and a drain electrode are denoted by reference numerals 13 and 14, respectively.

FIG. 8C illustrates another example of the bottom-gate transistor. In FIG. 8C, a substrate (n⁺ Si substrate which doubles as a gate electrode), a gate insulation layer (SiO₂), a channel layer (an oxide), a source electrode, and a drain electrode are denoted by reference numerals 21, 22, 25, 23, and 24, respectively.

The structure of the thin film transistor is not limited to the ones in the present embodiment, and an arbitrary top/bottom gate structure or staggered/inverse staggered structure may be used.

Components constituting the field effect transistor of the present invention will be described next in detail.

### (Channel Layer)

The channel layer will be described first.

The field effect transistor of the present invention uses for the channel layer an amorphous oxide that contains at least In and Mg (or Al). The reasons are as described above. An amorphous oxide containing In and Mg (In—Mg—O) and an amorphous oxide containing In, Mg, and Zn (In—Zn—Mg—O) are especially preferable materials. An amorphous oxide containing In, Sn, and Mg is employable as well.

Using an amorphous oxide containing In and Al (In—Al—O) and an amorphous oxide containing In, Al, and Zn (In—Zn—Al—O) as the channel layer is also preferable. An amorphous oxide containing In, Sn, and Al is employable as well.

(1) Channel Layer Formed from an Amorphous Oxide Containing At Least In and Mg

A case of using as the channel layer an amorphous oxide that contains at least In and Mg (In—Mg—O) will be described first. In employing In—Mg—O for the channel, there is a preferable In—Mg element ratio. The preferable element ratio, Mg/(In+Mg), is 0.1 or higher because, at this element ratio, an amorphous thin film can be obtained by sputter-deposition with the substrate temperature kept at room temperature. This is because, as described above, the polycrystalline phase where shapes and interconnection of polycrystalline grains are greatly varied depending on a film formation method causes fluctuations in characteristics of a TFT device.

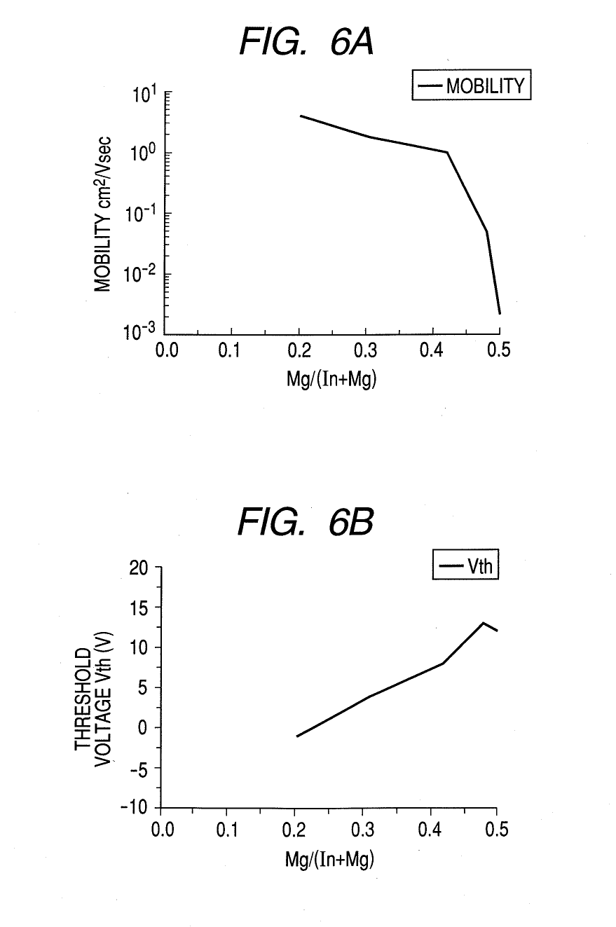

A further research was made on a thin film transistor that employs as its channel layer an amorphous oxide containing In and Mg. It was found as a result that the amorphous oxide was favorably employed as the channel layer at a specific element ratio Mg/(In+Mg) with respect to transistor characteristics of the thin film transistor. FIG. 6A illustrates an example of the In—Mg composition dependency of a thin film transistor manufactured with the use of In—Mg—O in relation to the field effect mobility. The graph of FIG. 6A illustrates that the field effect mobility increases as the Mg content is reduced. The required value of the field effect mobility varies depending on the use. For example, a preferable field effect mobility is 0.1 cm²/Vs or higher in liquid crystal displays, and 1 cm²/Vs or higher in organic EL displays. From these viewpoints, the In—Mg element ratio Mg/(In+Mg) is desirably 0.48 or lower and, more desirably, 0.42 or lower.

On the other hand, circuit building is easier when a threshold voltage Vth of a thin film transistor is 0 V or higher. FIG. 6B illustrates results of a research on the composition dependency of the threshold of an In—Mg—O-based thin film transistor. As illustrated in FIG. 6B, the element ratio Mg/(In+Mg) is desirably 0.2 or higher. A more desirable element ratio Mg/(In+Mg) is 0.3 or higher because, at this element ratio, Vth has a positive value.

It is concluded from the above that, in employing In—Mg—O for a channel layer of a thin film transistor, the In—Mg element ratio, Mg/(In+Mg), is desirably 0.1 or higher and 0.48 or lower, more desirably, 0.2 or higher and 0.48 or lower, and most desirably, 0.3 or higher and 0.42 or lower (see Examples below).

In the present invention, other elements than In, Mg, and O are allowed to be contained in an amorphous oxide if they are unavoidably contained elements or if their content does not affect the characteristics.

(2) Channel Layer Formed from an Amorphous Oxide Containing at Least In and Al

Next, a case of using as the channel layer an amorphous oxide that contains at least In and Al (In—Al—O) will be described. In this case, too, there is a preferable In—Al element ratio. The preferable element ratio, Al/(In+Al), is 0.15 or higher because, at this element ratio, an amorphous thin film can be obtained by sputter-deposition with the substrate temperature kept at room temperature. This is because, as described above, the polycrystalline phase where shapes and interconnection of polycrystalline grains are greatly varied depending on a film formation method causes fluctuations in characteristics of a TFT device.

A further research was made on a thin film transistor that employs as its channel layer an amorphous oxide containing In and Al (In—Al—O). It was found as a result that the amorphous oxide was favorably employed as the channel layer at a specific element ratio Al/(In+Al).

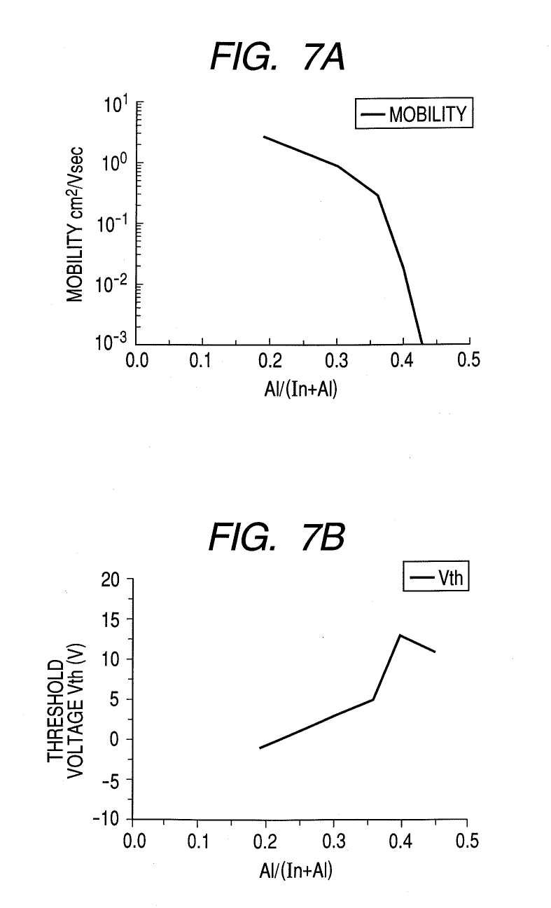

FIG. 7A illustrates an example of the In—Al composition dependency of a thin film transistor manufactured with the use of In—Al—O in relation to the field effect mobility. The graph of FIG. 7A illustrates that the field effect mobility increases as the Al content decreases. For example, the required value of the field effect mobility is preferably 0.1 cm²/Vs or higher in liquid crystal displays, and 1 cm²/Vs or higher in organic EL displays. From these viewpoints, the In—Al element ratio Al/(In+Al) is desirably 0.45 or lower, more desirably, 0.40 or lower and, most desirably, 0.3 or lower.

On the other hand, circuit building is easier when the threshold voltage Vth of a thin film transistor is 0 V or higher. FIG. 7B illustrates results of a research on the composition dependency of the threshold of an In—Al—O-based thin film transistor. As illustrated in FIG. 7B, the element ratio Al/(In+Al) is desirably 0.19 or higher. A more desirable element ratio Al/(In+Al) is 0.25 or higher because, at this element ratio, Vth has a positive value.

It is concluded from the above that, in employing In—Al—O for a channel layer of a thin film transistor, the In—Al element ratio, Al/(In+Al), is desirably 0.15 or higher and 0.45 or lower, more desirably, 0.19 or higher and 0.40 or lower, and most desirably, 0.25 or higher and 0.3 or lower (see Examples below).

In the present invention, other elements than In, Al, and O are allowed to be contained in an amorphous oxide if they are unavoidably contained elements or if their content does not affect the characteristics.

The thickness of the channel layer is desirably 10 nm or more and 200 nm or less, more desirably, 20 nm or more and 100 nm or less, and most desirably, 25 nm or more and 70 nm or less.

In order to obtain excellent TFT characteristics, the electric conductivity of an amorphous oxide film used as the channel layer is preferably set to 0.000001 S/cm or more and 10 S/cm or less. When the electric conductivity is larger than 10 S/cm, a normally-off transistor cannot be obtained and increasing the on/off ratio is not possible. In extreme cases, an application of gate voltage fails to turn on/off the current between the source and drain electrodes, and the TFT does not behave as a transistor. On the other hand, when the electric conductivity is smaller than 0.000001 S/cm, which makes the oxide film an insulator, the on-current cannot be sufficiently increased. In extreme cases, an application of gate voltage fails to turn on/off the current between the source and drain electrodes, and the TFT does not behave as a transistor.

In order to obtain the above-mentioned range of electric conductivity, the amorphous oxide film preferably has an electron carrier concentration of about 10¹⁴ to 10¹⁸/cm³, though the material composition of the channel layer also factors in. This amorphous oxide film can be formed by controlling, for example, the element ratio of metal elements, the partial pressure of oxygen during film formation, and conditions of annealing after the thin film is formed. Controlling the partial pressure of oxygen during film formation, in particular, helps to control mainly an oxygen deficiency in the thin film, thereby controlling the electron carrier concentration.

### (Gate Insulation Layer)

The gate insulation layer will be described next.

There is no particular preference for the material of the gate insulation layer as long as it has an excellent insulating property. Examples of the insulation layer include a silicon oxide SiOₓ, a silicon nitride SiNₓ, and a silicon oxynitride SiOₓN_{y}. In the present invention, SiO₂ whose composition does not conform to the stoichiometry is employable and, accordingly, a silicon oxide is expressed as SiOₓ. Further, in the present invention, Si₃N₄ whose composition does not conform to the stoichiometry is employable and, accordingly, a silicon nitride is expressed as SiN_{X}. A silicon oxynitride is expressed as SiOₓN_{y} for a similar reason.

In the case where the channel layer material contains Al, in particular, using a thin film whose major component is Al as the gate insulation layer gives the thin film transistor excellent characteristics.

By employing a thin film that has an excellent insulating property as this, the leak current can be reduced to about 10⁻⁸ amperes between the source and gate electrodes and between the drain and gate electrodes.

The adequate thickness of the gate insulation layer is one commonly employed, for example, about 50 to 300 nm.

### (Electrodes)

The source electrode, the drain electrode, and the gate electrode will be described next.

Each material of the source electrode, the drain electrode, and the gate electrode is not particularly limited as long as an excellent electric conductivity can be obtained and electric connection to the channel layer is possible. For example, a transparent conductive film containing, for example, In₂O₃:Sn or ZnO, or a metal electrode containing, for example, Au, Ni, W, Mo, Ag, or Pt can be used. Any layered structures including an Au—Ti layered structure are also employable.

### (Substrate)

The substrate will be described next.

As the substrate, a glass substrate, a plastic substrate, a plastic film, or the like can be used. The above-mentioned channel layer and the gate insulation layer are transparent with respect to visible light, and hence it is possible to obtain a transparent thin film transistor by using a transparent material as each material of the above-mentioned electrodes and substrate.

The following is a detailed description on a method of manufacturing the field effect transistor according to the present invention.

As a method of forming an oxide thin film, a gas phase process is provided such as a sputtering method (SP method), a pulsed laser deposition method (PLD method), and an electron beam deposition method. It should be noted that, among the gas phase processes, the SP method is suitable from the viewpoint of productivity. However, the film formation method is not limited to those methods.

Further, a substrate temperature at the time of film formation can be maintained substantially at room temperature in a state where the substrate is not intentionally heated. The method can be executed during a low-temperature process, and hence the thin film transistor can be formed on the substrate such as a plastic plate or a foil. Performing heat treatment on the formed oxide semiconductor in N₂ or in atmospheric air is also a preferred mode. The heat treatment can improve the TFT characteristics in some cases.

The semiconductor device (active matrix substrate) provided with the field effect transistor of the present invention, which is manufactured according to the above-mentioned method, can be composed of the transparent substrate and the transparent amorphous oxide TFT. When the transparent active matrix is applied to a display, an aperture ratio of the display can be increased. Particularly, when the transparent active matrix is used for the organic EL display, it is possible to employ a structure for taking out light also from the transparent active matrix substrate side (bottom emission). The semiconductor device according to this embodiment may be used for various uses of, for example, an ID tag or an IC tag.

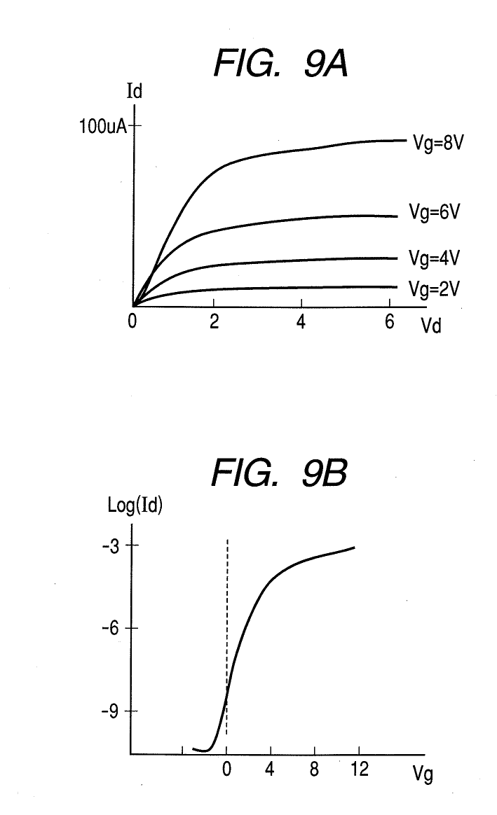

Characteristics of the field effect transistor of the present invention will be described next with reference to FIGS. 9A and 9B.

FIG. 9A illustrates an example of Id-Vd characteristics obtained at various voltages Vg, and FIG. 9B illustrates an example of Id-Vg characteristics (transfer characteristics) when Vd=6V. The difference in characteristics due to a difference in element ratio of an active layer can be expressed as a difference in field effect mobility p, threshold voltage (Vth), on/off ratio, and S value.

The field effect mobility can be obtained from characteristics of a linear region or a saturation region. For example, it is possible to employ a method of creating a graph representing √Id-Vg from the results of the transfer characteristics so as to obtain the field effect mobility from an inclination of the graph. In the description of the present invention, unless otherwise noted, evaluation is performed by the method.

While there are some methods of obtaining the threshold value, the threshold voltage Vth can be obtained from, for example, an x-intercept of the graph representing √Id-Vg.

The on/off ratio can be obtained from a ratio of a largest Id value to a smallest Id value in the transfer characteristics.

The S value can be obtained from an inverse number of an inclination of a graph representing Log(Id)-Vd which is created from the results of the transfer characteristics.

The difference in transistor characteristics is not limited to the above, but can be also represented by various parameters.

Described below are Examples of the present invention. However, the present invention is not limited to the following examples.

### Example 1

In this example, the top-gate TFT device illustrated in FIG. 8A was manufactured with an In—Mg—O-based amorphous oxide as a channel layer.

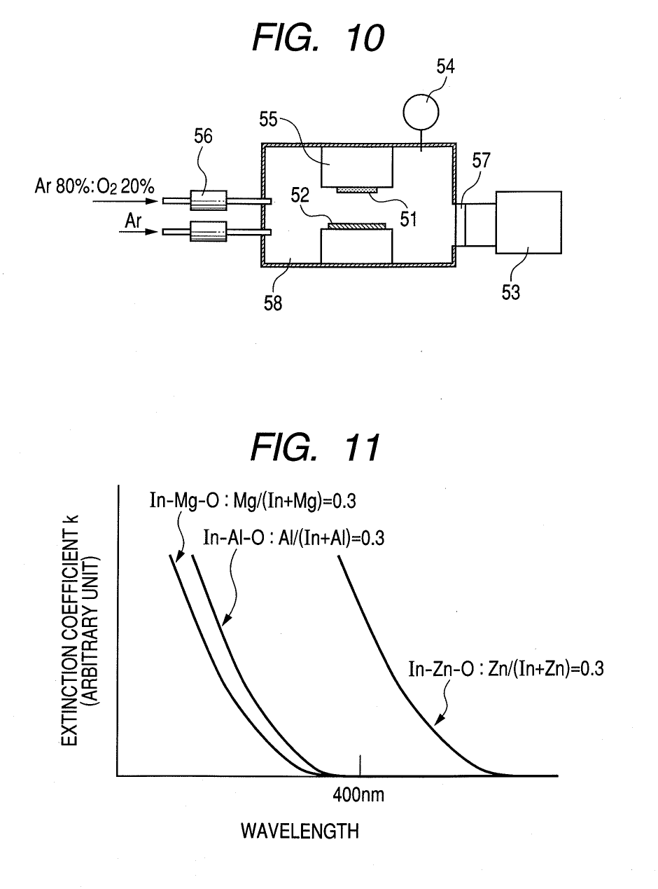

First, an In—Mg—O-based amorphous oxide film was formed as the channel layer on a glass substrate (1737 manufactured by Corning Incorporated). The film was formed by high-frequency sputtering in a mixed atmosphere of argon gas and oxygen gas with the use of an apparatus illustrated in FIG. 10. In FIG. 10, a sample, a target, a vacuum pump, a vacuum gauge, and a substrate holder are denoted by reference numerals 51, 52, 53, 54, and 55, respectively. A gas flow rate controller 56 is provided for each gas introduction system. A pressure controller and a film formation chamber are denoted by reference numerals 57 and 58, respectively. The vacuum pump 53 is an exhaust unit for exhausting the interior of the film formation chamber 58. The substrate holder 55 is a unit for keeping the substrate on which the oxide film is to be formed within the film formation chamber. The target 52 is a solid material source, and is placed across from the substrate holder. The apparatus is further provided with an energy source (not-shown, high-frequency power source) for making the material evaporate from the target 52, and a unit for supplying gas to the interior of the film formation chamber.

The apparatus has two gas introduction systems, one is for argon and the other is for mixture gas of argon and oxygen (Ar:O₂=95:5). With the gas flow rate controllers 56, which enable the apparatus to control the respective gas flow rates individually, and the pressure controller 57, which is used to control the exhaust speed, a given gas atmosphere can be obtained in the film formation chamber.

In this example, 2-inch sized targets of In₂O₃ and MgO (purity: 99.9%) were used to form an In—Mg—O film by simultaneous sputtering. The input RF power was 40 W and 180 W for the former and latter targets. The atmosphere in the film formation was set such that the total pressure was 0.4 Pa and the gas flow rate ratio was Ar:O₂=200:1. The film formation rate and the substrate temperature were set to 9 nm/min. and 25° C., respectively. After the film formation, the film was subjected to an annealing process for 30 minutes at 280° C. in atmospheric air.

A glance angle X-ray diffraction (thin film method, incident angle: 0.5°) was performed on the surface of the obtained film. No obvious diffraction peaks were detected, which indicated that the formed In—Mg—O-based film was an amorphous film.

A spectroscopic ellipsometry measurement showed that the films had a roughness in root mean square (Rrms) of about 0.5 nm and a thickness of about 40 nm. An X-ray fluorescent (XRF) analysis was performed to show that the metal composition ratio of the film was In:Mg=6:4. The electric conductivity, the electron carrier concentration, and the electron mobility were estimated to be about 10⁻³ S/cm, 3×10¹⁶/cm³, and about 2 cm²/Vs, respectively.

The drain electrode 14 and the source electrode 13 were formed next by patterning through photolithography and the lift-off method. The material of the electrodes was an Au—Ti layered film. The thickness of the Au layer was 40 nm and the thickness of the Ti layer was 5 nm.

The gate insulation layer 12 was formed next by patterning through photolithography and the lift-off method. The gate insulation layer 12 was an SiOₓ film formed by sputter-deposition to a thickness of 150 nm. The specific dielectric constant of the SiOₓ film was about 3.7.

The gate electrode 15 was also formed through photolithography and the lift-off method. The channel length and the channel width were 50 μm and 200 μm, respectively. The material of the electrode was Au, and the thickness of the Au film was 30 nm. A TFT device was manufactured in the manner described above.

Next, characteristics of the thus manufactured TFT device were evaluated.

FIGS. 9A and 9B illustrate examples of current-voltage characteristics of the TFT device which were measured at room temperature. FIG. 9A illustrates Id-Vd characteristics whereas FIG. 9B illustrates Id-Vg characteristics. In FIG. 9A, the dependency of a source-drain current Id on a drain voltage Vd was measured as Vd changed under application of a constant gate voltage Vg.

As illustrated in FIG. 9A, saturation (pinch off) was observed around Vd=6 V, which was a typical semiconductor transistor behavior. Gain characteristics were such that the threshold voltage was about 2 V at Vd=6 V. At 10 V, Vg caused a current of about 1.0×10⁻⁴ A to flow as the source-drain current Id.

The on/off ratio of the transistor exceeded 10⁷. The field effect mobility calculated from output characteristics was about 2 cm²/Vs in the saturation region.

The TFT manufactured in this example had excellent reproducibility, and fluctuations in characteristics between multiple devices manufactured were small.

By employing the novel amorphous oxide, In—Mg—O, for the channel layer, excellent transistor characteristics were thus obtained.

### Comparative Example 1

In this Comparative Example, a top-gate TFT device using In—Ga—O as its channel layer was manufactured by the same method that was employed in Example 1. The metal composition ratio of the thin film was In:Ga=7:3.

Next, the optical response characteristic of the TFT device of Example 1 which used In—Mg—O for the channel and the optical response characteristic of the TFT device of Comparative Example 1 which used In—Ga—O for the channel were evaluated.

Transistor characteristics (Id-Vg) of the TFT device of Example 1 were evaluated first in a dark place and under light irradiation. As illustrated in FIG. 2, the off-current of the TFT had a very small value (a) in a dark place, whereas the off-current increased to (b) and (c) when the TFT was evaluated in terms of characteristics while irradiated with monochromatic light at the wavelength of 500 nm and 350 nm, respectively. In short, the off-current increases under light irradiation, and thereby the on/off ratio is reduced.

Subsequently, a comparison was made between the TFT device of Example 1 and the TFT device of Comparative Example 1 by measuring the off-current while the TFT devices were in a dark place, irradiated with 500-nm monochromatic light, and irradiated with 350-nm monochromatic light as illustrated in FIG. 1. As can be seen in the graph of FIG. 1, the increase in off-current under light irradiation was smaller with In—Mg—O than with In—Ga—O. This proves that the TFT device of Example 1 which employs In—Mg—O for the channel has a superior stability against light irradiation to that of the TFT device of Comparative Example 1 which employs In—Ga—O for the channel.

A TFT device according to the present invention which is very stable against light as described above can be expected to find use in an operating circuit of an organic light emitting diode and the like.

### Example 2

In this example, the In—Mg composition dependency was examined in a thin film transistor with a channel layer that contains In and Mg as major components.

This example employed the combinatorial method for TFT fabrication (channel layer formation) in order to examine the material composition dependency of the channel layer. In other words, TFT compositional library was made with the use of a method of forming, by sputtering, thin films of oxides varied in composition on a single substrate. However, it does not need to be this combinatorial method, and targets of a given composition may be prepared to form a film, or thin films of desired compositions may be formed by controlling the input power for multiple targets separately.

An In—Mg—O film was formed with the use of a ternary grazing incidence sputtering apparatus. With the target positioned at an angle with respect to the substrate, the composition of a film on the substrate surface is varied due to a difference in distance from the target. As a result, a film having a wide compositional distribution could be obtained. In forming the In—Mg—O film, two targets of In₂O₃ and one target of MgO were simultaneously powered by sputtering. The input RF power was set to 20 W and 180 W for the former and the latter, respectively. The atmosphere in the film formation was set such that the total pressure was 0.35 Pa and the gas flow rate ratio was Ar:O₂=200:1. The substrate temperature was set to 25° C.

Physical properties of the thus formed film were evaluated by X-ray fluorescent analysis, spectroscopic ellipsometry, X-ray diffraction, and four-point probe resistivity measurement. A bottom-gate, top-contact TFTs using as its n-channel layer In—Mg—O films were also manufactured by way of trial and their electrical properties were evaluated at room temperature.

The thickness of the channel layers was measured by spectroscopic ellipsometry. It was found as a result that the amorphous oxide film had a thickness of about 50 nm. Film thickness distribution among TFTs on the substrate is within ±10%.

It was confirmed through an X-ray diffraction (XRD) measurement that the formed In—Mg—O film was amorphous in compositional regions where the element ratio, Mg/(In+Mg), was 0.1 or higher. In some of films where the element ratio Mg/(In+Mg) was smaller than 0.1, a diffraction peak of the crystal was observed. It was concluded from the above-mentioned results that an amorphous thin film could be obtained by setting the element ratio, Mg/(In+Mg) in an In—Mg—O film to 0.1 or higher.

The sheet resistance of the In—Mg—O films was measured by the four-point probe method and the thickness of the films was measured by spectroscopic ellipsometry in order to obtain the resistivity of the films. As a result, it was confirmed that the resistivity changed in relation to changes in In—Mg composition ratio, and the resistance was found to be low on the In-rich films (where the element ratio Mg/(In+Mg) was small) and high on the Mg-rich films.

Next, the resistivity of the In—Mg—O films when the oxygen flow rate in the film formation atmosphere had been changed was obtained. It was found as a result that an increase in oxygen flow rate raised the resistance of the In—Mg—O films. This is probably due to the lessening of oxygen deficiency and resultant lowering of the electron carrier concentration. It was also found that the composition range in which the resistance was suitable for the TFT active layer changed in relation to changes in oxygen flow rate.

Results of measuring changes in resistivity with time are illustrated in FIG. 3. No changes in resistivity with time were observed in the In—Mg—O-based thin film over a wide composition range (range in which element ratio Mg/(In+Mg) was 0.2 to 0.6). On the other hand, an In—Zn—O film and an In—Sn—O film that were formed in the same manner as the In—Mg—O film exhibited tendency to decline in resistivity with time. This proved that the In—Mg—O film had a superior environmental stability.

Next, characteristics and composition dependency of the thin film transistor having the In—Mg—O film as the n-channel layer were examined. The transistor had the bottom-gate structure illustrated in FIG. 8C. First, an In—Mg—O composition gradient film was formed on an Si substrate having a thermal oxide film, and then processes including patterning and electrode formation were performed, thereby forming on a single substrate a lot of devices including active layers having different compositions from one another. As like this many thin film transistors with various channel compositions were manufactured on a 3-inch wafer and their electrical properties are evaluated. The thin film transistors had a bottom-gate, top-contact structure that used n⁺-Si for the gate electrode, SiO₂ for the insulation layer, and Au/Ti for the source and drain electrodes. The channel width and the channel length were 150 μm and 10 μm, respectively. The source-drain voltage used in the FET evaluation was 6 V.

In the TFT characteristics evaluation, the electron mobility was obtained from the inclination of √Id (Id: drain current) with respect to the gate voltage (Vg), and the current on/off ratio was obtained from the ratio of the maximum Id value and the minimum Id value. An intercept with respect to the Vg axis when √Id was plotted in relation to Vg was treated as the threshold voltage, and the minimum value of dVg/d (log Id) was set as an S value (voltage value necessary to increase the current by one digit).

Changes in TFT characteristics in relation to changes in In—Mg composition ratio were examined by evaluating TFT characteristics at various positions on the substrate. It was found as a result that the TFT characteristics were varied depending on the position on the substrate, namely, the In—Mg composition ratio.

In an In-rich composition, the on-current is relatively large, and the off-current cannot be sufficiently suppressed by Vg, and the threshold was a negative value. In an Mg-rich composition, on the other hand, the off-current was relatively small, and the on-current cannot be sufficiently enhanced, and the on-threshold voltage took a positive value. Thus, “normally-off characteristics” were obtained for TFTs in Mg-rich composition. However, the on-current was small and the field effect mobility was low in the Mg-rich composition.

A device (C) of FIG. 4, in which the element ratio Mg/(In+Mg) was 0.42 had an on/off ratio of more than six digits, which indicated relatively good characteristics.

The characteristics of the above-mentioned TFT device were improved by performing an annealing process on the TFT device at 300° C. in atmospheric air. The TFT characteristics (Id-Vg) after the annealing are illustrated in FIG. 4. The composition dependency of the TFT characteristics exhibits the same tendency as before the annealing. However, it can be seen that the composition range in which the TFT characteristics were excellent was widened. For example, excellent characteristics were obtained in (B) in which the element ratio Mg/(In+Mg) was 0.3 and (C) in which the element ratio Mg/(In+Mg) was 0.42.

FIG. 6A illustrates the In:Mg composition dependency of the field effect mobility. It can be seen that the field effect mobility increases as the Mg content is reduced. A field effect mobility of 0.1 cm²/Vs or higher was obtained when the In—Mg element ratio, Mg/(In+Mg), was 0.48 or lower. A field effect mobility of 1 cm²/Vs or higher was obtained when the In—Mg element ratio, Mg/(In+Mg), was 0.4 or lower.

FIG. 6B illustrates the composition dependency of the threshold voltage. Circuit building is easier when the threshold voltage Vth of a thin film transistor is 0 V or higher. As illustrated in FIG. 6B, the element ratio Mg/(In+Mg) is preferably 0.2 or higher because, at this ratio, Vth has a positive value.

The electron mobility, current on/off ratio, threshold, and S value of a device that obtained excellent transistor characteristics were 2 cm²/Vs, 1×10⁸, 4 V, and 1.5 V/dec, respectively.

### Example 3

In this example, a channel layer was formed from an In—Al—O-based amorphous oxide, and the top-gate TFT device illustrated in FIG. 8A that used this channel layer was manufactured and evaluated by the same method that was employed in Example 1.

2-inch sized targets of In₂O₃ and Al₂O₃ (purity: 99.9%) were used to form an In—Al—O film by simultaneous sputtering. The input RF power was 60 W and 180 W for the former and latter targets. The atmosphere in the film formation was set such that the total pressure was 0.4 Pa and the gas flow rate ratio was Ar:O₂=150:1. The film formation rate and the substrate temperature were set to 11 nm/min. and 25° C., respectively. Subsequently, the film was subjected to an annealing process for 30 minutes at 280° C. in atmospheric air.

A glance angle X-ray diffraction (thin film method, incident angle: 0.5°) was performed on the surface of the obtained film. No obvious diffraction peaks were detected, which indicated that the formed In—Al—O-based film was an amorphous film.

A spectroscopic ellipsometry measurement showed that the thin film had a roughness in root mean square (Rrms) of about 0.5 nm and a thickness of about 40 nm. An X-ray fluorescent (XRF) analysis was performed to show that the metal composition ratio of the thin film was In:Al=7:3.

The electric conductivity, the electron carrier concentration, and the electron mobility were estimated to be about 10⁻³ S/cm, 5×10¹⁶/cm³, and about 3 cm²/Vs, respectively.

Thereafter, the same steps as in Example 1 were taken to manufacture the top-gate TFT.

Next, the electrical characteristics of the manufactured TFT device were evaluated.

In FIG. 9A, the dependency of a source-drain current Id on a drain voltage Vd was measured as Vd changed under application of a constant gate voltage Vg. As illustrated in FIG. 9A, saturation (pinch off) was observed around Vd=6 V, which was a typical semiconductor transistor behavior. Gain characteristics were such that the threshold voltage of the gate voltage Vg was about 4 V at Vd=6 V. At 10 V, Vg caused a current of about 1.0×10⁻⁴ A to flow as the source-drain current Id.

The on/off ratio of the transistor exceeded 10⁷. The field effect mobility calculated from output characteristics was about 1.5 cm²/Vs in the saturation region.

The TFT manufactured in this example had excellent reproducibility, and fluctuations in characteristics between multiple devices manufactured were small.

By employing the novel amorphous oxide, In—Al—O, for the channel layer, excellent transistor characteristics were thus obtained.

The optical response characteristic of the TFT device of this example which used In—Al—O for the channel layer was evaluated next. Transistor characteristics (Id-Vg) of the TFT device were evaluated in a dark place and under light irradiation. As illustrated in FIG. 2, the off-current of the TFT had a very small value a in a dark place, whereas the off-current increased to b and c when the TFT was evaluated under irradiation with monochromatic light at 500 nm and 350 nm, respectively. FIG. 1 compares the off-current measured when TFTs are in a dark place, when the TFTs are irradiated with 500-nm monochromatic light, and when the TFTs are irradiated with 350-nm monochromatic light. As can be seen in the graph, the increase in off-current under light irradiation was smaller with In—Al—O than with In—Ga—O. This proves that the TFT device that employs In—Al—O for the channel has a superior stability against light irradiation to that of the TFT device that employs In—Ga—O for the channel.

A TFT device according to the present invention which is greatly stable against light as described above can be expected to find use in an operating circuit of an organic light emitting diode and the like.

### Example 4

In this example, the In—Al composition dependency was examined in a thin film transistor with a channel layer that contained In and Al as major components in the same manner as in Example 2.

In—Al—O films were formed with the use of a ternary grazing incidence sputtering apparatus. In forming the In—Al—O films, two targets of In₂O₃ and one target of Al₂O₃ were simultaneously powered by sputtering. The input RF power was set to 30 W and 180 W for the former and the latter, respectively. The atmosphere in the film formation was set such that the total pressure was 0.35 Pa and the gas flow rate ratio was Ar:O₂=150:1. The substrate temperature was set to 25° C.

Physical properties of the thus formed film were evaluated by X-ray fluorescent analysis, spectroscopic ellipsometry, X-ray diffraction, and four-point probe resistivity measurement. A bottom-gate, top-contact TFTs using as its n-channel layer an In—Al—O films were also manufactured by way of trial and their electrical properties are evaluated at room temperature.

The thickness of the films was measured by spectroscopic ellipsometry. It was found as a result that the amorphous oxide films had a thickness of about 50 nm. Film thickness distribution among TFT channels on the substrate is within ±10%.

It was confirmed through an X-ray diffraction (XRD) measurement that the formed In—Al—O film was amorphous in compositions in which the element ratio, Al/(In+Al), was 0.15 or higher.

The sheet resistance of the In—Al—O film were measured by the four-point probe method and the thickness of the film was measured by spectroscopic ellipsometry to obtain the resistivity of the films. As a result, it was confirmed that the resistivity changed in relation to changes in In—Al composition ratio, and the resistance was found to be low on the In-rich composition and high on the Al-rich composition.

Next, the resistivity of the In—Al—O films when the oxygen flow rate in the film formation atmosphere was changed was obtained. It was found as a result that an increase in oxygen flow rate raised the resistance of the In—Al—O films. This is probably due to the lessening of oxygen deficiency and resultant lowering of the electron carrier concentration. It was also found that the composition range in which the resistance was suitable for the TFT active layer changed in relation to changes in oxygen flow rate.

Results of measuring changes in resistivity with time are illustrated in FIG. 3. No changes in resistivity with time were observed in the In—Al—O-based thin film over a wide composition range. On the other hand, an In—Zn—O film and an In—Sn—O film that were formed in the same manner as the In—Al—O film exhibited a decline in resistivity with time. This proved that the In—Al—O film had a superior environmental stability.

Next, characteristics and composition dependency of the thin film transistor having the In—Al—O film as the re-channel layer were examined.

As in Example 2, changes in TFT characteristics in relation to changes in In—Al composition ratio were examined by evaluating TFT characteristics at various positions on the substrate. It was found as a result that the TFT characteristics were varied depending on the position on the substrate, namely, the In—Al composition ratio.

In an In-rich composition, the on-current is relatively large, and the off-current cannot be sufficiently suppressed by Vg and the threshold was a negative value. In an Al-rich composition, on the other hand, the off-current is relatively small, and the on-current cannot be sufficiently enhanced, and the threshold voltage took a positive value. Thus, “normally-off characteristics” were obtained for the TFTs with Al-rich composition. However, the drain current was small and the field effect mobility was low in the Al-rich composition.

A device in which the element ratio Al/(In+Al) was 0.36 had an on/off ratio of more than six digits, which indicated relatively good characteristics.

The characteristics of the above-mentioned TFT device were improved by performing an annealing process on the TFT device at 300° C. in atmospheric air. The TFT characteristics (Id-Vg) after the annealing are illustrated in FIG. 5. The composition dependency of the TFT characteristics exhibits the same tendency as before the annealing. However, it can be seen that the composition range in which the TFT characteristics were excellent was widened. For example, excellent characteristics were obtained in (B) in which the element ratio Al/(In+Al) was 0.3 and (C) in which the element ratio Al/(In+Al) was 0.36.

FIG. 7A illustrates the In:Al composition dependency of the field effect mobility. It can be seen that the field effect mobility increases as the Al content is reduced. A field effect mobility of 0.1 cm²/Vs or higher was obtained when the In—Al element ratio, Al/(In+Al), was 0.4 or lower. A field effect mobility of 1 cm²/Vs or higher was obtained when the In—Al element ratio, Al/(In+Al), was 0.3 or lower.

FIG. 7B illustrates the composition dependency of the threshold voltage. Circuit building is easier when the threshold voltage Vth of a thin film transistor is 0 V or higher. As illustrated in FIG. 7B, the element ratio Al/(In+Al) is preferably 0.25 or higher because, at this ratio, Vth has a positive value.

The electron mobility, current on/off ratio, threshold, and S value of a device in this example that obtained excellent transistor characteristics were 1 cm²/Vs, 1×10⁸, 4 V, and 1.6 V/dec, respectively.

### Example 5

In this example, the bottom-gate TFT device illustrated in FIG. 8B was manufactured on a plastic substrate, with an In—Zn—Mg—O-based amorphous oxide as a channel layer.

First, a polyethylene terephthalate (PET) film was prepared as a substrate. On this PET substrate, the gate electrode and the gate insulation layer were formed. These layers were patterned through photolithography and the lift-off method. The gate electrode was formed from a Ta film with a thickness of 50 nm. The gate insulation layer was an SiOₓN_{y} film (silicon oxynitride film) formed by sputtering to have a thickness of 150 nm. The specific dielectric constant of the SiOₓN_{y} film was about 6.

Next, the channel layer of the transistor was formed, which was by patterned through photolithography and the lift-off method. The channel layer was formed from an In—Zn—Mg—O-based amorphous oxide, which contains In, Zn and Mg at a composition ratio of In:Zn:Mg=4:6:1. The channel length and channel width of the transistor were 60 μm and 180 μm, respectively. The In—Zn—Mg—O-based amorphous oxide film was formed by high-frequency sputtering in a mixed atmosphere of argon gas and oxygen gas.

In this example, three targets (material sources) were used to form a film by simultaneous deposition. The three targets were respectively 2-inch sized, sintered compacts (purity: 99.9%) of In₂O₃, MgO, and ZnO. By controlling the input RF power for these targets separately, an oxide thin film having a desired In:Zn:Mg composition ratio was obtained. The atmosphere was set such that the total pressure was 0.5 Pa and the gas flow rate ratio was Ar:O₂=100:1. The substrate temperature was set to 25° C.

The thus formed oxide film was found to be an amorphous film because no obvious diffraction peaks were detected in X-ray diffraction (thin film method, incident angle: 0.5°). The thickness of the amorphous oxide film was about 30 nm. An optical absorption spectrum analysis revealed that the formed amorphous oxide film had a forbidden energy band-gap of about 3 eV and was transparent with respect to visible light. The source electrode, the drain electrode, and the gate electrode were formed from a transparent conductive film that contained In₂O₃ and Sn and that had a thickness of 100 nm. The bottom-gate TFT device was manufactured in this manner.

Next, the thus manufactured TFT device was evaluated in terms of characteristics.

The on/off ratio of the TFT of this example measured at room temperature exceeded 10⁹. The calculated field effect mobility was about 7 cm²/Vs. Excellent transistor operation was ensured when the element ratio, Mg/(In+Zn+Mg), of the amorphous oxide material was 0.1 or higher and 0.48 or lower.

The thin film transistor of this example which uses the In—Zn—Mg—O-based oxide semiconductor as the channel was higher in stability against light, compared to the thin film transistor that uses as the channel In—Zn containing no Mg. Containing Mg, the transistor of this example was also improved in environmental stability.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-322148, filed Dec. 13, 2007, which is hereby incorporated by reference herein in its entirety.

1. A field effect transistor comprising at least a channel layer, a gate insulation layer, a source electrode, a drain electrode, and a gate electrode,
wherein the channel layer is made of an amorphous oxide material that contains at least In and Mg, and
wherein an element ratio, expressed by Mg/(In+Mg), of the amorphous oxide material is 0.1 or higher and 0.48 or lower.

2. A field effect transistor according to claim 1, wherein the element ratio, expressed by Mg/(In+Mg) of the amorphous oxide material is 0.2 or higher and 0.48 or lower.

3. A field effect transistor according to claim 1, wherein the element ratio, expressed by Mg/(In+Mg) of the amorphous oxide material is 0.3 or higher and 0.42 or lower.

4. A field effect transistor according to claim 1,
wherein the amorphous oxide material forming the channel layer contains Zn, and
wherein an element ratio, expressed by Mg/(In+Zn+Mg), of the amorphous oxide material is 0.1 or higher and 0.48 or lower.

5. A field effect transistor comprising at least a channel layer, a gate insulation layer, a source electrode, a drain electrode, and a gate electrode,
wherein the channel layer is formed from an amorphous oxide material that contains at least In and Al, and
wherein an element ratio, expressed by Al/(In+Al), of the amorphous oxide material is 0.15 or higher and 0.45 or lower.

6. A field effect transistor according to claim 5, wherein the element ratio, expressed by Al/(In+Al) of the amorphous oxide material is 0.19 or higher and 0.40 or lower.

7. A field effect transistor according to claim 5, wherein the element ratio, expressed by Al/(In+Al) of the amorphous oxide material is 0.25 or higher and 0.3 or lower.

8. A field effect transistor according to claim 1, wherein the gate insulation layer is made of a silicon oxide.

9. A display comprising the field effect transistor according to claim 1 being used as a driving device of a display device.
